(19) United States
(12) Patent Application Publication
(10) Pub. No.: US 2025/0164720 A1
(43) Pub. Date: May 22, 2025

(54) LASER MODULE AND SYSTEMS USING THE SAME

(71) Applicant: Xscape Photonics Inc., Fort Lee, NJ (US)

(72) Inventors: Hyundai Park, Goleata, CA (US); Ferdinand Mendoza, Newark, CA (US); Vivek Raghunathan, Mountain View, CA (US); Li Li, San Ramon, CA (US)

(21) Appl. No.: 18/953,766

(22) Filed: Nov. 20, 2024

Related U.S. Application Data
(60) Provisional application No. 63/600,827, filed on Nov. 20, 2023.

(51) Int. Cl. G02B 6/42; H01S 5/0234

(52) U.S. Cl. CPC G02B 6/4274; G02B 6/4204; H01S 5/0234

(57) ABSTRACT

A laser module includes: an interposer including a surface including planar and recessed portions, the interposer including multiple electrical contact pads on the planar portion; a semiconductor laser assembly flip-chip mounted on the surface of the interposer, the semiconductor laser assembly including a subassembly and a semiconductor laser die mounted to the subassembly, the subassembly including electrical contact pads electrically connected to corresponding electrical contact pads on the planar portion of the surface of the interposer, and the semiconductor laser die extending at least partially into the recessed portion in the surface of the interposer; and a photonic integrated circuit (PIC) flip-chip mounted on the planar portion of the surface of the interposer, the PIC being spaced apart from the semiconductor laser assembly, the PIC including a light coupling port arranged to receive light emitted from the semiconductor laser die during operation of the laser module.

### CLAIM OF PRIORITY

This application claims priority to U.S. Patent Application Ser. No. 63/600,827, filed on Nov. 20, 2023, the entire contents of which are hereby incorporated by reference.

### BACKGROUND

Silicon photonic devices utilize silicon as an optical medium. Because silicon is used as a substrate for most integrated circuits, silicon photonic devices can be hybrid devices that integrate both optical and electronic components into a single integrated circuit package.

### SUMMARY

Photonic devices can include both a laser assembly and a photonic integrated circuit (PIC) co-packaged on a common substrate, with the laser assembly generating a laser beam to be in-coupled to the PIC. In these devices, accurately aligning the heights between the laser assembly and the PIC is important to efficiently in-couple a laser beam from the laser assembly into the PIC.

The present disclosure provides a module including a flip-chip mounted laser assembly and a flip-chip mounted photonic integrated circuit (PIC). The mounting reduces beam misalignment between the laser assembly and the PIC in at least one dimension. Further, the module can include a supporting structure, e.g., an interposer, shaped to accommodate a planar portion and a recessed portion, which provides space for a laser package disposed on a bottom surface of the laser assembly.

The disclosed devices can improve alignment, e.g., to within a micron or less, between a laser assembly and a PIC in a module without the use of additional spacers or shims. Additionally, since the alignment is more likely to be within a tolerance threshold using the devices described here, the process of making a module can be simplified compared to conventional methods in order to achieve sufficiently accurate alignment. For example, the assembly process can include fewer active alignment steps (or eliminate such steps entirely), thereby reducing the processing time, e.g., by as much as 10 times, and increasing throughput.

For example, a typical integrated circuit package can include both a laser assembly and a photonic integrated circuit. A first waveguide disposed on an upper surface of the laser assembly out-couples the laser beam, and a second waveguide disposed on an upper surface of the photonic integrated circuit in-couples the laser beam. Since the first and second waveguides are disposed near upper surfaces of the laser assembly and the photonic integrated circuit, respectively, a height difference between the photonic integrated circuit and the laser assembly can lead to misalignment. In the present disclosure, however, this potential for misalignment is eliminated by flip-chip mounting both the laser assembly and the photonic integrated circuit.

To compensate for the misalignment in a typical integrated circuit package, e.g., non-flip-chip mounted, a spacer is placed under the shorter of the laser assembly and the photonic integrated circuit to reduce the height difference. However, adding a spacer introduces more room for error and requires an extra component in the integrated circuit package and an additional step of placing the spacer while forming the integrated circuit package. The devices, systems, and methods of the present disclosure, however, avoid the need for placing a shim or additional spacer to align the heights of the laser assembly and the photonic integrated circuit.

In a first general aspect, a laser module includes: an interposer including a surface including a planar portion and a recessed portion, the interposer including multiple electrical contact pads on the planar portion; a semiconductor laser assembly flip-chip mounted on the surface of the interposer, the semiconductor laser assembly including a subassembly and a semiconductor laser die mounted to the subassembly, the subassembly including one or more electrical contact pads electrically connected to a corresponding one or more of the multiple electrical contact pads on the planar portion of the surface of the interposer, and the semiconductor laser die extending at least partially into the recessed portion in the surface of the interposer; and a photonic integrated circuit (PIC) flip-chip mounted on the planar portion of the surface of the interposer, the PIC being spaced apart from the semiconductor laser assembly, the PIC including a light coupling port arranged to receive light emitted from the semiconductor laser die during operation of the laser module.

In a second general aspect, a laser module includes: an interposer including multiple electrical contact pads; a semiconductor laser die including one or more electrical contact pads each electrically connected to a corresponding electrical contact pad on the interposer; and a photonic integrated circuit (PIC) flip-chip mounted on a surface of the interposer, the PIC being spaced apart from the semiconductor laser die, the PIC including an in-coupling port arranged to receive light emitted from the semiconductor laser die at an edge of the PIC during operation of the laser module.

In a third general aspect, a method includes: etching a surface of an interposer to define a recessed portion and a planar portion in the surface of the interposer; aligning a semiconductor laser assembly including a semiconductor laser die relative to the recessed portion; flip-chip mounting the semiconductor laser assembly on the interposer, the flip-chip mounting including bonding one or more first electrical contact pads on a surface of the semiconductor laser assembly to corresponding electrical contact pads on the planar portion of the interposer, with the semiconductor laser die at least partially extending into a recess defined by the recessed portion; and flip-chip mounting a photonic integrated circuit (PIC) on the interposer, the flip-chip mounting including bonding one or more electrical contact pads on a surface of the PIC to corresponding electrical contact pads on the planar portion of the interposer, the PIC being spaced from the semiconductor laser assembly and aligned to receive a laser beam emitted from the laser assembly.

Implementations may include one or more of the following features.

In some implementations, the subassembly includes a first waveguide extending in a first plane, the PIC includes a second waveguide extending in a second plane parallel to the first plane and parallel to the planar portion, and a vertical distance, along a vertical direction perpendicular to the first and second planes, between the first and second waveguides is 1 μm or less.

In some implementations, the PIC includes one or more second electrical contact pads each electrically connected to a corresponding electrical contact pad on the planar portion of the surface of the interposer.

In some implementations, the one or more electrical contact pads of the subassembly have a same height along the vertical direction as the one or more second electrical contact pads of the PIC.

In some implementations, the one or more electrical contact pads of the subassembly and the one or more second electrical contact pads of the PIC have a vertical dimension in a range of 100 μm to 750 μm, and the multiple electrical contact pads on the planar portion of the interposer have a vertical dimension in a range of 10 μm to 300 μm.

In some implementations, the recessed portion of the interposer is parallel to a plane defined by first and second lateral directions. The recessed portion of the interposer can define a cavity having a length in a range of 1 mm-15 mm along the first lateral direction, a width in a range of 1 mm-15 mm, along the second lateral direction and a depth in a range of 200 micron to 800 micron along a vertical direction perpendicular to the first and second lateral directions.

In some implementations, the planar portion of the interposer is parallel to a plane defined by first and second lateral directions. A lateral distance, along either the first lateral direction or the second lateral direction, between the semiconductor laser assembly and the PIC can be in a range of hundreds of μm to 5 mm.

In some implementations, the laser module further includes one or more free space optical components between the semiconductor laser assembly and the PIC.

In some implementations, the one or more free space optical components include at least one of a lens and an isolator.

In some implementations, the laser module further includes an electrically conductive element electrically coupling the semiconductor laser die to the subassembly.

In some implementations, the laser module further includes a fiber connector mounted on the interposer and including a coupling unit configured to receive a fiber array.

In some implementations, the semiconductor laser die includes an out-coupling port arranged to emit the light, and difference between a first height between a surface of the interposer and the out-coupling port is equal to a second height between the surface of the interposer and the in-coupling port is 1 μm or less.

In some implementations, the laser module further includes a semiconductor optical amplifier mounted on the interposer. The PIC can be disposed between the semiconductor laser die and the semiconductor optical amplifier.

In some implementations, the laser module further includes a fiber connector mounted on the interposer and including a coupling unit configured to receive a fiber array. The semiconductor optical amplifier can be configured to optically couple to the fiber connector. In some implementations, etching the surface of the interposer includes one of dry etching, wet etching, or deep reactive ion etching (DRIE).

In some implementations, the semiconductor laser assembly includes an output port the PIC includes an input port positioned to receive the laser beam from the output port and couple the laser beam into a waveguide in the PIC, the flip-chip mounting of the laser assembly and PIC further including aligning the laser assembly and the PIC so that a difference between a first height between the planar portion of the interposer and the output port of the laser assembly and a second height between the planar portion of the interposer and the input port of the PIC is 1 μm or less.

In some implementations, the aligning is performed passively.

In some implementations, the aligning is performed without focusing the laser beam emitted from the output port.

The details of one or more embodiments of the subject matter of this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1A depicts a laser module including a laser assembly and a photonic integrated circuit mounted on an interposer, the laser assembly mounted above a recessed portion of the interposer.

FIG. 1B depicts a cross-sectional view of the laser assembly from FIG. 1A along line I-I′.

FIG. 1C depicts a cross-sectional view of the photonic integrated circuit from FIG. 1A along line II-II′.

FIG. 2A depicts a conventional laser module.

FIGS. 2B and 2C depict the same cross-sectional views as FIGS. 1B and 1C, respectively, but with labeled regions A, B, C, and D.

FIGS. 2D, 2E, 2F, and 2G respectively depict regions A, B, C, and D from FIGS. 2B and 2C.

FIG. 2H schematically depicts the alignment of input and output ports within a laser module. FIG. 2I depicts a plan view of the laser module of FIG. 2H.

FIG. 3A depicts a device including a laser module.

FIG. 3B depicts a device including a laser module where the laser assembly is mounted above a planar portion of the interposer.

FIG. 4A depicts a device including a laser module and a pluggable fiber connector.

FIG. 4B depicts a device including a laser module and a semiconductor optical amplifier.

FIG. 5 is a flowchart depicting a process of forming a laser module.

Like reference numbers and designations in the various drawings indicate like elements.

### DETAILED DESCRIPTION

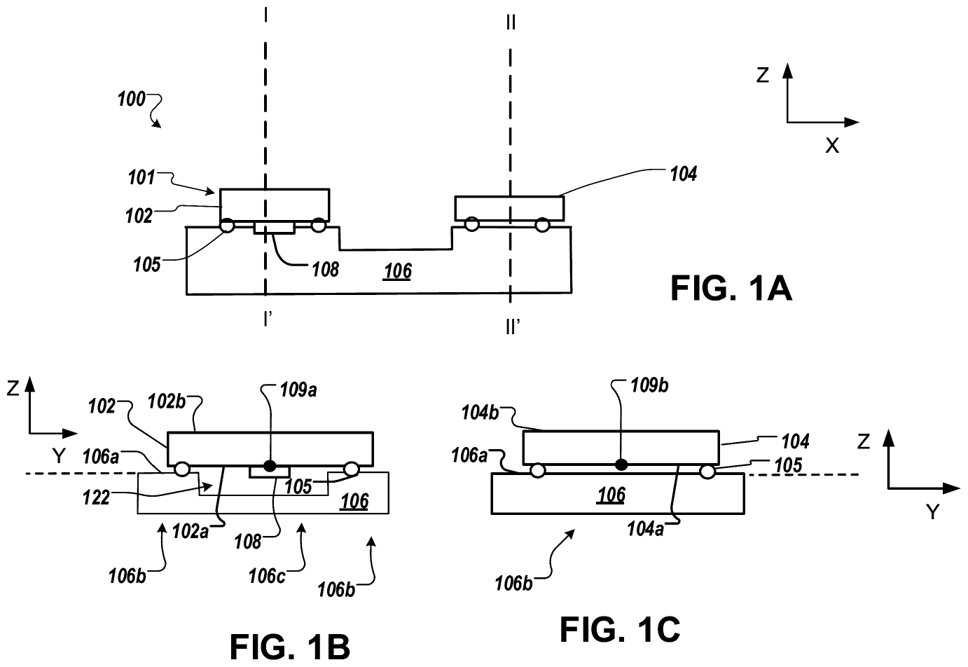

With reference to FIGS. 1A, 1B, and 1C, a laser module 100 includes a semiconductor laser assembly 101, a photonic integrated circuit (PIC) 104, and an interposer 106. Contacts 105 electrically and physically couple each of the laser assembly 101 and the PIC 104 to the interposer 106. The laser assembly 101 includes a subassembly 102 and a laser die 108. The laser assembly 101 and PIC 104 are spaced apart from each other along a horizontal direction, e.g., the X axis.

Both of the laser assembly 101 and the PIC 104 are flip-chip mounted on the interposer, so that ports for in-coupling or out-coupling light are positioned closer to a first surface, e.g., surfaces 102a or 104a, of the subassembly 102 or PIC 104, that faces the surface 106a of the interposer 106 than to a second surface, e.g., surfaces 102b or 104b, of the subassembly 102 or PIC 104 opposite the respective first surface.

The interposer 106 includes both planar portions 106b and a recessed portion 106c. Although the recessed portion 106c is not visible from the view of FIG. 1A, e.g., along the Y axis, the recessed portion 106c is visible from the cross-sectional view of FIG. 1B along the X axis, which is perpendicular to the view of FIG. 1A. FIG. 1B is a cross-sectional view along line I-I′ in FIG. 1A, and FIG. 1C is a cross-sectional view along line II-II′ in FIG. 1A.

The contacts 105 are only placed on the planar portions 106b of the interposer 106, e.g., not on the recessed portion 106c. The contacts 105 can be flip-chip bumps, solder bumps, solder balls, solder columns, Cu-pillars, Au-stud bumps, Cu—Cu direct bonds, flip-chip joints made with anisotropic films, or more generally, any electrically conductive joint.

Each of the laser assembly 101 and the PIC 104 are mounted on the planar portions 106b, which have a constant height, e.g., marked by the dotted lines in FIGS. 1B and 1C, along the vertical axis, e.g., the Z axis. The recessed portion 106c is recessed relative to the vertical direction, thereby forming a cavity 122 in the surface 106a of the interposer 106. Since the laser assembly 101 is mounted above the recessed portion 106c, the cavity 122 provides space for the laser die 108 to be disposed on the bottom of the subassembly 102 while still having clearance relative to the interposer 106. Advantageously, this prevents the laser die 108 from touching the interposer 106, thereby preventing stress on the laser diode, which can be brittle.

In some implementations, the cavity has dimensions, e.g., length, width, and height, on the order of several hundred microns. For example, a lateral dimension of the cavity, e.g., measured along the X or Y direction, can be in the range of 1-5 mm. The depth of the cavity, e.g., as measured along the Z direction, can be in a range of 200 μm-800 μm. In some implementations, the cavity can have rounded corners, e.g., not be exactly rectangular.

Light generated by the laser die 108 out-couples from the laser assembly 101 through port 109a and in-couples into the PIC 104 through port 109b. As a result of each of the laser assembly 101 and the PIC 104 being flip-chip mounted, the heights of the ports 109a and 109b relative to the planar portion 106b of the interposer 106, e.g., the distances between the ports 109a or 109b and the dotted lines in FIGS. 1B and 1C along the z-axis, are roughly the same. For example, a difference between these two distances can be one micron or less, e.g., 0.5 μm or less, 0.4 μm or less, 0.3 μm or less, 0.25 μm or less, 0.1 μm or less, 0.05 μm or less, or hundreds of nanometers or less.

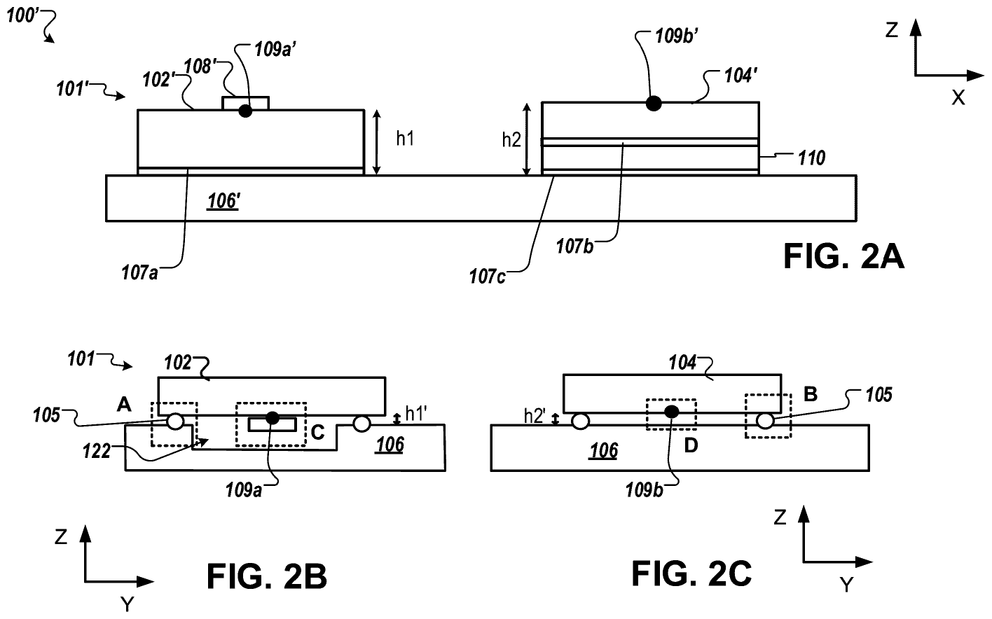

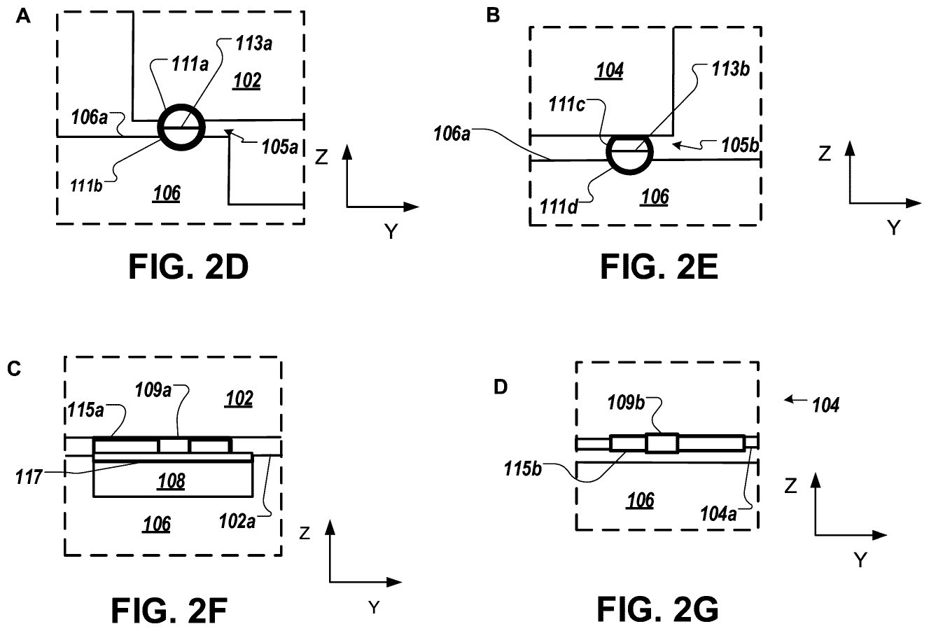

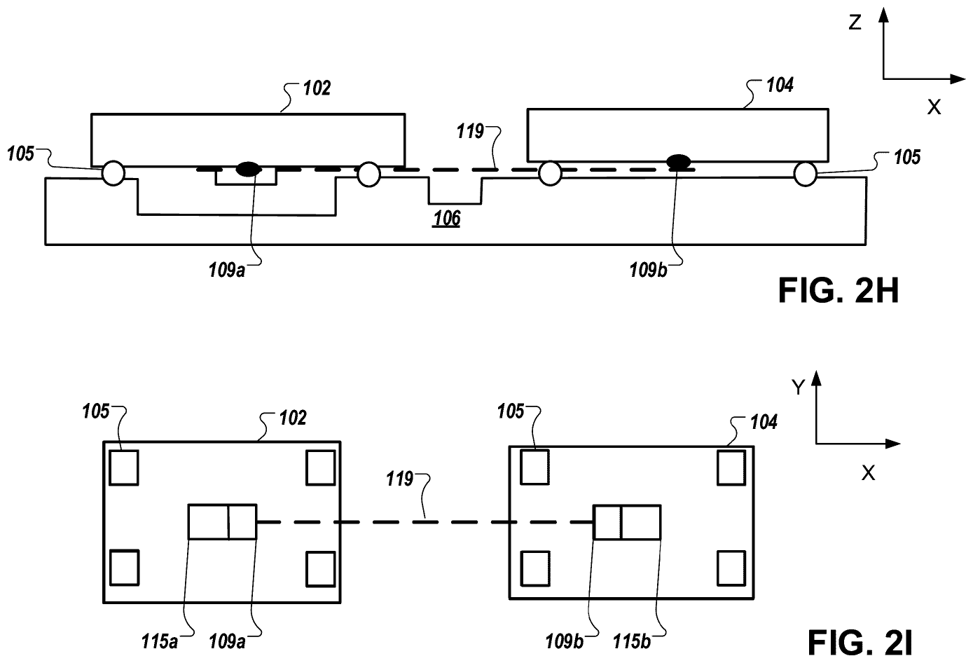

As a comparative example, FIG. 2A depicts a conventional device 100′ including a laser assembly 101′ and a PIC 104′ mounted on an interposer 106′. Unlike the laser module 100, the laser assembly 101′ and the PIC 104′ are not flip-chip mounted, so ports 109a′ and 109b′ for out- and in-coupling light are located near upper surfaces of subassembly 102′ and PIC 104′, respectively. To align the heights h1 and h2 of the ports 109a′ and 109b′, respectively, a spacer 110 is positioned between the PIC 104′ and the interposer 106′. An adhesive layer 107a bonds the subassembly 102′ to the interposer 106′, an adhesive layer 107b bonds the PIC 104′ to the spacer 110, and an adhesive layer 107c bonds the spacer 110 to the interposer 106′. The height h1 of the port 109a′ is the sum of the heights of the subassembly 102a′ and the adhesive layer 107a, and the height h2 of the port 109b′ is the sum of the heights of the PIC 104′, the spacer 110, and the adhesive layers 107b and 107c. Thus, the height h1 depends on at least two variables, and the height h2 depends on at least four variables. This dependence poses problems for accurate alignment, especially since each of the components themselves can have local variations in height.

In contrast, with reference to FIGS. 2B and 2C, the heights h1′ and h2′ of the ports 109a and 109b, respectively, depend on fewer variables. Because the laser assembly 101 and the PIC 104 are flip-chip mounted on the interposer 106, the heights h1′ and h2′ of the ports 109a and 109b do not depend on the heights of the subassembly 102 or the PIC 104, respectively. Rather, the heights h1′ and h2′ of the ports 109a and 109b depend on the heights of the contacts 105. Additionally, because the laser assembly 101 and PIC 104 are mounted with discrete contacts 105, e.g., instead of an adhesive layer, there is an optical path for light to travel from port 109a to port 109b underneath the laser assembly 101 and PIC 104.

FIGS. 2D and 2E respectively depict regions A and B including contacts 105 and marked by dotted lines in FIGS. 2B and 2C. The contacts 105 can include multiple components. For example, the contact 105a between the subassembly 102 and the interposer 106 includes a first electrical contact pad 111a, which can be part of the subassembly 102, and a corresponding, second electrical contact pad 111b coupled to the surface 106a of the interposer 106. The first and second electrical contact pads 111a and 111b are bonded to each other at interface 113a. Similarly, the contact 105b between the PIC 104 and the interposer 106 includes a first electrical contact pad 111c and a second electrical contact pad 111d coupled to the surface 106a of the interposer 106. The first and second electrical contact pads 111c and 111d are bonded to each other at interface 113b.

The heights of each of the electrical contact pads 111 can be selected such that the heights h1′ and h2′ of the ports 109a and 109b are approximately the same. For example, the sum of the heights of the electrical contact pads 111a and 111b can be equal to the sum of the heights of the electrical contact pads 111c and 111d, e.g., the height of contact 105a is equal to the height of contact 105b. For example, the electrical contact pads 111a and 111c can have a height as measured along the Z direction in the range of 100 μm-750 μm. The electrical contact pads 111b and 111d can have a height as measured along the Z direction in the range of 10 μm-300 μm If the heights of the contacts 105 for each of the laser assembly 101 and the PIC 104 are the same, the ports for out- and in-coupling laser light are approximately the same.

In some implementations, the electrical contact pads 111 are solder balls. For example, the solder balls can have a pitch of tens of microns, e.g., 200 μm or less, 150 μm or less, 100 μm or less, 50 μm or less, 25 μm or less, or 10 μm or less. The size of the solder balls can be on the order of one's of microns, e.g. 100 μm or less, 50 μm or less, 25 μm or less, 10 μm or less, 5 μm or less, or 2 μm or less.

FIGS. 2F and 2G respectively depict regions C and D including light-coupling ports and marked by dotted lines in FIGS. 2B and 2C. Each of the ports 109a and 109b can be coupled to a respective waveguide for guiding optical signals to/from a respective port. For example, the subassembly 102 includes a waveguide 115a located closer to the first surface 102a of the subassembly 102 facing the interposer 106 than to a second surface 102 opposite the first surface 102a. Similarly, the PIC 104 includes a waveguide 115b located closer to the first surface 104a of the PIC 104 facing the interposer 106 than to a second surface opposite the first surface 104a. Port 109a is an out-coupling port coupled to the waveguide 115a, and port 109b is an in-coupling port coupled to the waveguide 115b. Each of the waveguides 115a and 115b extends in a plane parallel to the planar portion 106b of the interposer 106, e.g., in the XY plane.

With reference to FIGS. 2G and 2I, the ports 109a and 109b being vertically aligned means that a vertical distance between the two planes of the waveguides 115a and 115b is a micron or less. For example, FIG. 2H schematically depicts, e.g., distances are not to scale, the ports 109a and 109b being vertically aligned, as horizontal line 119 along a first lateral direction, e.g., a line in the XY plane along the X direction, intersects both ports 109a and 109b when viewed along a second lateral direction, e.g., the Y direction.

The ports 109a and 109b can also be horizontally aligned. For example, FIG. 2I is a plan view, along the vertical direction e.g., −Z direction, of the bottom of the module. The ports 109a and 109b on each of the waveguides 115a and 115b, respectively, are aligned, as horizontal line 119 along the first lateral direction, e.g., a line in the XY plane along the X direction, intersects both ports 109a and 109b when viewed along a vertical direction, e.g., the Z direction. From FIGS. 2H and 2I the alignment of the ports 109a and 109b is visible, since the ports 109a and 109b are aligned in a first horizontal direction (the Y direction), spaced apart in a second horizontal direction (X direction), and aligned in a vertical direction (Z direction).

In some implementations, a conductive element 117 electrically couples the laser die 108 to the subassembly 102. In some implementations, there are additional layers (although not depicted in FIG. 2F) positioned on the laser die 108, so that the laser die 108 is not the lowermost layer of the laser assembly 101.

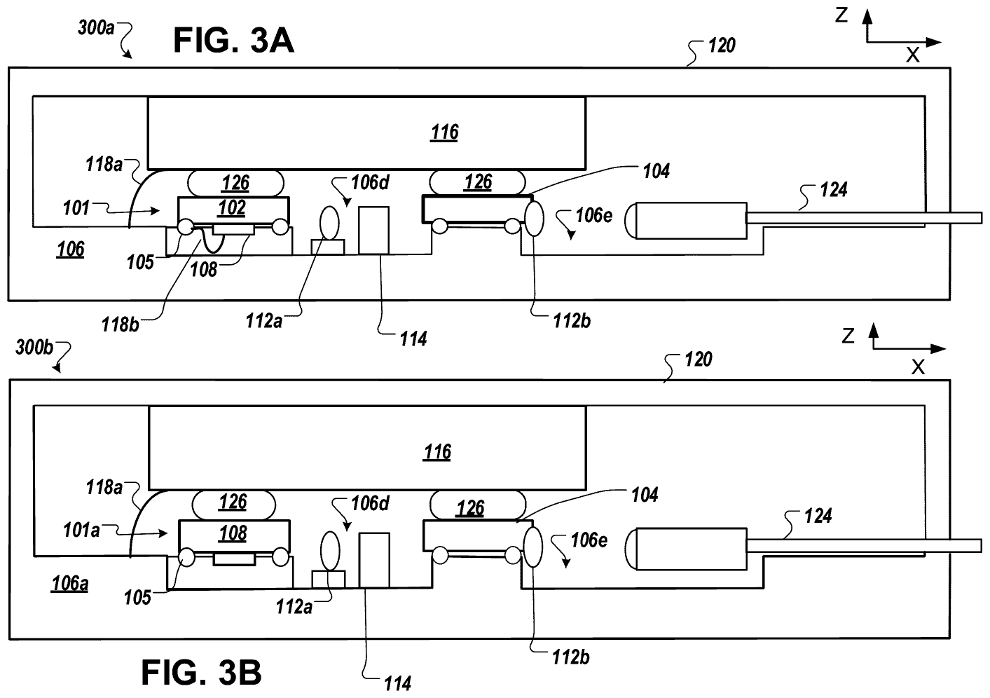

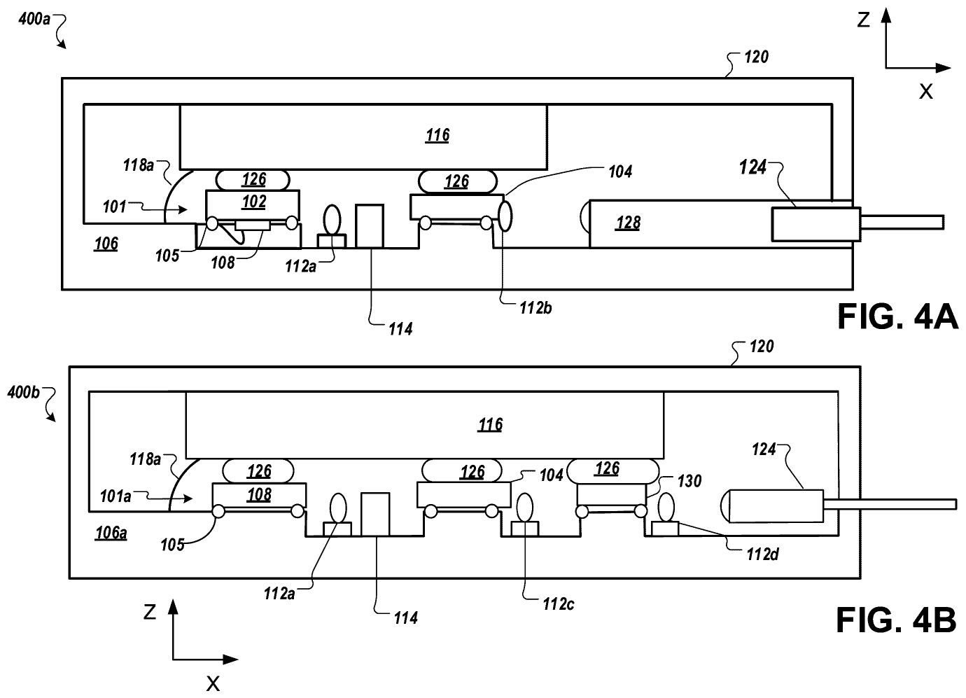

With reference to FIG. 3A, a device 300a includes the module 100, as well as other components. In FIGS. 3A, 3B, 4A, and 4B, although part of the laser die 108 would be obscured by the interposer from a side view, the portions filled with grid lines are depicted as transparent to make more components in the figures visible.

For example, the device 300a includes a laser assembly 101 including a subassembly 102 and a laser die 108 and a PIC 104, each of which are mounted on an interposer 106.

Since the laser assembly 101 and the PIC 104 are spaced apart from each other, e.g., in a range of hundreds of microns to 5 mm, aligning the laser assembly 101 and PIC 104 can increase the optical efficiency of the optical coupling between the laser assembly 101 and the PIC 104, since they are not butt-coupled. During an alignment process, free space optical components, such as lens 112a and isolator 114, are placed between the subassembly 102 and the PIC 104.

In addition to a recessed portion 106c for accommodating the laser die 108, the interposer 106 in device 300a includes recessed portions 106d and 106e. Recessed portion 106d is located between the laser assembly 101 and the PIC 104. The portion of the interposer 106 between the laser assembly 101 and the PIC 104 being recessed allows for the lens 112a and the isolator 114 to be at the correct height to receive the laser beam generated by the laser die 108. The isolator 114 can prevent back reflection coming from the laser die 108 during the alignment process. Recessed portion 106e is located between the PIC 104 and a fiber package 124. Similarly, the portion of the interposer 106 beneath the fiber package 124 being recessed allows for the fiber package 124 to be at the correct height for in- and out-coupling light to and from the PIC 104.

The fiber package 124 includes an array of fibers, each of which can in- and out-couple light to and from the PIC 104. A lens 112b can be placed on the PIC 104 to focus in- and out-coupled light.

A wire bond 118a connects the interposer 106 to a thermoelectric cooler (TEC) 116. During the alignment process, the TEC 116 cools the module to prevent unwanted heat from distorting optical components, which can prevent the wavelength of the generated laser beam from straying from a target wavelength. Optionally, a wire bond 118b electrically connects the subassembly 102 to the laser die 108.

Thermally conductive adhesives 126, which allow for the flow of heat from the subassembly 102 and the PIC 104 to the TEC 116, are located between the subassembly 102 and the TEC 116 and between the PIC 104 and the TEC 116. In some implementations, the subassembly 102 includes a ceramic, such as aluminum nitride, to help dissipate heat. The thermally conductive adhesives 126 can be conformal such that they compensate for the height difference between the subassembly 102 and the PIC 104, since there can be a difference between the distance from the TEC 116 to the subassembly 102 and the distance from the TEC 116 to the PIC 104.

A glass lid and frame 120 can enclose the components within the device 300a.

With reference to FIG. 3B, a device 300b can be substantially similar to device 300a, with some differences that will be explained. Repeated description of components of device 300b will be omitted for brevity. In device 300b, a laser assembly 101a does not include subassembly 102. Rather, the laser die 108 is directly bonded to an interposer 106a through contacts 105.

In this example, the laser die 108 is flip-chip mounted, so the out-coupling port is closer to a first surface of the laser die 108 facing the interposer 106a than to a second surface opposite the first surface. As a result, the height of a port for out-coupling light does not depend on a height of a subassembly of the laser assembly 101a. Accordingly, ports of the laser die 108 and the PIC 104 can be aligned as long as the contacts 105 have substantially the same height along the Z axis.

In device 300b, because the laser die 108 is directly bonded to the interposer 106a, the laser assembly 101a can be mounted above a planar portion rather than a recessed portion of the interposer, and the laser die 108 can still have clearance relative to the interposer. In other words, the laser die 108 does not have to at least partially extend into a cavity to avoid contacting the interposer 106a.

With reference to FIG. 4A, a device 400a can be substantially similar to device 300a, with some differences that will be explained. Repeated description of components of device 400a will be omitted for brevity. Compared to device 300a, device 400a additionally includes a fiber connector 128, e.g., a pluggable PIC connector. The fiber connector 128 makes replacing fibers possible, e.g., if one fiber package 124 breaks, another fiber package can replace the broken fiber package.

With reference to FIG. 4B, a device 400b can be substantially similar to device 300b, with some differences that will be explained. Repeated description of components of device 400b will be omitted for brevity. Compared to device 300b, device 400b includes a semiconductor optical amplifier (SOA) 130 located between the PIC 104 and the fiber package 124. Similarly to the laser assembly 101a and the PIC 104, the SOA 130 is mounted on a planar portion of the interposer 106a. Device 400a demonstrates how the disclosed modules and devices can be scaled to incorporate multiple coupled photonic dice with low loss.

A thermally conductive adhesive 126 can be located between the SOA 130 and the TEC 116. In some implementations, the SOA 103 can include a submount that is mounted on the interposer 106a. Instead of a lens being coupled to the PIC 14, lens 112c is mounted within a recessed region of the interposer 106a between the PIC and the SOA 130. Additionally, lens 112d is mounted within a recessed region of the interposer 106a between the SOA 130 and the fiber package 124.

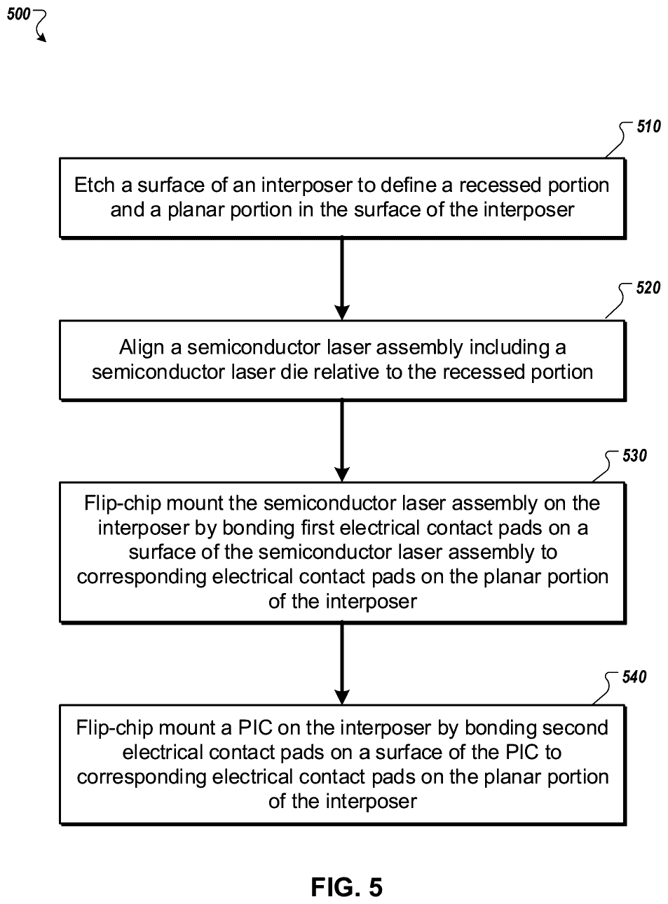

FIG. 5 is a flow diagram of a method 500 for forming devices, such as module 100.

The method 500 includes etching a surface of an interposer to define a recessed portion and a planar portion in the surface of the interposer (510). For example, the interposer can be interposer 106 with surface 106a. The interposer can include silicon, e.g., glass. The planar portion can correspond to planar portion 106b, and the recessed portion can correspond to recessed portion 106c. In some implementations, etching can include dry etching, wet etching, or deep reactive ion etching (DRIE).

The method 500 includes aligning a semiconductor laser assembly including a semiconductor laser die relative to the recessed portion (520). Aligning the semiconductor laser assembly can include aligning the semiconductor laser assembly above the recessed portion, such that a footprint of the semiconductor laser die is completely within a footprint of the recessed portion of the interposer.

The method 500 includes flip-chip mounting the semiconductor laser assembly on the interposer by bonding first electrical contact pads on a surface of the semiconductor laser assembly to corresponding electrical contact pads on the planar portion of the interposer (530). For example, the corresponding electrical contact pads can be electrical contact pads 111b. In some implementations, the electrical contact pads are formed through bonding, coupling, and/or soldering. For example, the first electrical contact pads can correspond to electrical contact pads 111a, and the electrical contact pads on the planar portion can correspond to electrical contact pads 111b. In some implementations, bonding the semiconductor laser assembly to the interposer electrically couples the semiconductor laser assembly to the interposer.

As a result of the alignment and mounting, the semiconductor laser die at least partially extends into the recess defined by the recessed portion. For example, the laser die 108 extends partially into the cavity 122 defined by the recessed portion 106c in FIG. 1B.

The method 500 includes mounting a PIC in a flip-chip orientation by bonding second electrical contact pads on a surface of the PIC to the electrical contact pads on the planar portion of the interposer (540). For example, the second electrical contact pads can correspond to electrical contact pads 111c, and the electrical contact pads on the planar portion can correspond to electrical contact pads 111d.

As a result of the alignment and mounting, the semiconductor laser assembly and the PIC are spaced apart from each other, with the PIC being aligned to receive a laser beam emitted from the laser assembly.

The order of steps in the method 500 described above is illustrative only, and the method 500 can be performed in different orders. For example, the PIC can be mounted before the semiconductor laser assembly is aligned or mounted.

In some implementations, the method 500 can include additional steps, fewer steps, or some of the steps can be divided into multiple steps. For example, the method 500 can include assessing how well the semiconductor laser assembly is aligned relative to the PIC.

This assessment can include determining a difference in heights between optical ports for emitting and receiving light generated by the semiconductor laser assembly. For example, the optical ports can be coupled to waveguides on each of the semiconductor laser assembly and PIC. Alignment can result in a difference between heights of the waveguides relative to the planar portion of the interposer being 1 μm or less. In some implementations, aligning is performed passively only, e.g., not using a lens, such as lens 112a, to focus the laser beam.

In addition to the embodiments of the attached claims and the embodiments described above, the following numbered embodiments are also innovative.

While this specification contains many specific implementation details, these should not be construed as limitations on the scope of what is being claimed, which is defined by the claims themselves, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially be claimed as such, one or more features from a claimed combination can in some cases be excised from the combination, and the claim may be directed to a subcombination or variation of a subcombination.

Similarly, while operations are depicted in the drawings and recited in the claims in a particular order, this by itself should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results.

1. A laser module, comprising:
an interposer comprising a surface comprising a planar portion and a recessed portion, the interposer comprising a plurality of electrical contact pads on the planar portion;
a semiconductor laser assembly flip-chip mounted on the surface of the interposer, the semiconductor laser assembly comprising a subassembly and a semiconductor laser die mounted to the subassembly, the subassembly comprising one or more electrical contact pads electrically connected to a corresponding one or more of the plurality of electrical contact pads on the planar portion of the surface of the interposer, and the semiconductor laser die extending at least partially into the recessed portion in the surface of the interposer; and
a photonic integrated circuit (PIC) flip-chip mounted on the planar portion of the surface of the interposer, the PIC being spaced apart from the semiconductor laser assembly, the PIC comprising a light coupling port arranged to receive light emitted from the semiconductor laser die during operation of the laser module.

2. The laser module of claim 1, wherein the subassembly comprises a first waveguide extending in a first plane, the PIC comprises a second waveguide extending in a second plane parallel to the first plane and parallel to the planar portion, and a vertical distance, along a vertical direction perpendicular to the first and second planes, between the first and second waveguides is 1 μm or less.

3. The laser module of claim 1, wherein the PIC comprises one or more second electrical contact pads each electrically connected to a corresponding electrical contact pad on the planar portion of the surface of the interposer.

4. The laser module of claim 3, wherein the one or more electrical contact pads of the subassembly have a same height, along a vertical direction perpendicular to the planar portion of the interposer, as the one or more second electrical contact pads of the PIC.

5. The laser module of claim 4, wherein the one or more electrical contact pads of the subassembly and the one or more second electrical contact pads of the PIC have a vertical dimension in a range of 100 μm to 750 μm, and the plurality of electrical contact pads on the planar portion of the interposer have a vertical dimension in a range of 10 μm to 300 μm.

6. The laser module of claim 1, wherein the recessed portion of the interposer is parallel to a plane defined by first and second lateral directions, and
wherein the recessed portion of the interposer defines a cavity having a length in a range of 1 mm-15 mm along the first lateral direction, a width in a range of 1 mm-15 mm, along the second lateral direction and a depth in a range of 200 micron to 800 micron along a vertical direction perpendicular to the first and second lateral directions.

7. The laser module of claim 1, wherein the planar portion of the interposer is parallel to a plane defined by first and second lateral directions,
wherein a lateral distance, along either the first lateral direction or the second lateral direction, between the semiconductor laser assembly and the PIC is in a range of hundreds of μm to 5 mm.

8. The laser module of claim 1, further comprising one or more free space optical components between the semiconductor laser assembly and the PIC.

9. The laser module of claim 8, wherein the one or more free space optical components comprise at least one of a lens and an isolator.

10. The laser module of claim 1, further comprising an electrically conductive element electrically coupling the semiconductor laser die to the subassembly.

11. The laser module of claim 10, further comprising a fiber connector mounted on the interposer and comprising a coupling unit configured to receive a fiber array.

12. A laser module comprising:
an interposer comprising a plurality of electrical contact pads;
a semiconductor laser die comprising one or more electrical contact pads each electrically connected to a corresponding electrical contact pad on the interposer; and
a photonic integrated circuit (PIC) flip-chip mounted on a surface of the interposer, the PIC being spaced apart from the semiconductor laser die, the PIC comprising an in-coupling port arranged to receive light emitted from the semiconductor laser die at an edge of the PIC during operation of the laser module.

13. The laser module of claim 12, wherein the semiconductor laser die comprises an out-coupling port arranged to emit the light, and difference between a first height between a surface of the interposer and the out-coupling port is equal to a second height between the surface of the interposer and the in-coupling port is 1 μm or less.

14. The laser module of claim 12, further comprising a semiconductor optical amplifier mounted on the interposer, wherein the PIC is disposed between the semiconductor laser die and the semiconductor optical amplifier.

15. The laser module of claim 14, further comprising a fiber connector mounted on the interposer and comprising a coupling unit configured to receive a fiber array,
wherein the semiconductor optical amplifier is configured to optically couple to the fiber connector.

16. A method comprising:
etching a surface of an interposer to define a recessed portion and a planar portion in the surface of the interposer;
aligning a semiconductor laser assembly comprising a semiconductor laser die relative to the recessed portion;
flip-chip mounting the semiconductor laser assembly on the interposer, the flip-chip mounting comprising bonding one or more first electrical contact pads on a surface of the semiconductor laser assembly to corresponding electrical contact pads on the planar portion of the interposer, with the semiconductor laser die at least partially extending into a recess defined by the recessed portion; and
flip-chip mounting a photonic integrated circuit (PIC) on the interposer, the flip-chip mounting comprising bonding one or more electrical contact pads on a surface of the PIC to corresponding electrical contact pads on the planar portion of the interposer, the PIC being spaced from the semiconductor laser assembly and aligned to receive a laser beam emitted from the laser assembly.

17. The method of claim 16, wherein etching the surface of the interposer comprises one of dry etching, wet etching, or deep reactive ion etching (DRIE).

18. The method of claim 16, wherein the semiconductor laser assembly comprises an output port the PIC comprises an input port positioned to receive the laser beam from the output port and couple the laser beam into a waveguide in the PIC, the flip-chip mounting of the laser assembly and PIC further comprising aligning the laser assembly and the PIC so that a difference between a first height between the planar portion of the interposer and the output port of the laser assembly and a second height between the planar portion of the interposer and the input port of the PIC is 1 μm or less.

19. The method of claim 18, wherein the aligning is performed passively.

20. The method of claim 18, wherein the aligning is performed without focusing the laser beam emitted from the output port.
